(19) United States
(12) Patent Application Publication
(10) Pub. No.: US 2025/0098125 A1
(43) Pub. Date: Mar. 20, 2025

(54) DATE CENTER LOCAL COOLING SYSTEM WITH PRE-COOLING CHILLER

(71) Applicant: SAMHWA ACE CO., LTD., Seoul (KR)

(72) Inventors: Byoung Nam CHOI, Siheung-si, Gyeonggi-do (KR); Woo Jung KIM, Incheon (KR); Deok Soo JUNG; Min Geon GO

(73) Assignee: SAMHWA ACE CO., LTD., Seoul (KR)

(21) Appl. No.: 18/570,645

(22) PCT Filed: Jun. 18, 2021
(86) PCT No.: PCT/KR2021/007682

§ 371 Date: Jul. 17, 2024

(30) Foreign Application Priority Data
Jun. 17, 2021 (KR) 10-2021-0078738

(51) Int. Cl. H05K 7/20

(52) U.S. Cl. CPC H05K 7/20836; H05K 7/20209; H05K 7/20318; H05K 7/20327; H05K 7/20354; H05K 7/20409; H05K 7/20827

(57) ABSTRACT

A data center local cooling system with a pre-cooling chiller includes a pre-cooling chiller that is installed outside a data center; a plurality of refrigerant distributors that are connected to the pre-cooling chiller through a cooling water flow line through which the cooling water flows and a third refrigerant flow line through which a third refrigerant flows; a plurality of in-row air conditioners that are disposed between server racks in an interior of the data center, are connected to the refrigerant distributors through the third refrigerant flow line through which the third refrigerant flows; and a control unit that is electrically connected to the pre-cooling chiller, the plurality of refrigerant distributors, and the plurality of in-row air conditioners, and controls operations of the pre-cooling chiller, the plurality of refrigerant distributors, and the plurality of in-row air conditioners based on an temperature of external air.

### TECHNICAL FIELD

The present invention relates to a data center local cooling system with a pre-cooling chiller, and more specifically, to a data center local cooling system with a pre-cooling chiller, in which in response to a temperature of outside air, the pre-cooling chiller may be operated in an optimal operation mode, thereby minimizing the amount of power used to cool a server room, a plurality of in-row air conditioners that cool indoor air are installed between server racks in a computer room, thereby circulating the refrigerant cooled by the in-row air conditioners by using a refrigerant distributor that cools a liquid refrigerant, so that as the liquid refrigerant is used as a refrigerant to cool indoor air, highly efficient heat exchange is possible by using latent heat of evaporation of the refrigerant, and as sensible heat exchange is possible indoors, the refrigerant exists as a gas at room temperature, which prevents condensation from forming inside the server room.

### BACKGROUND

In general, a data center is closer to an industrial building where maintaining the operating environment of IT equipment (servers) in an optimal state is a priority rather than a space where people live.

In other words, the focus has been on environmental control rather than energy conservation to protect equipment and provide stable operating conditions This does not consider active energy saving measures because the economic loss caused by errors or breakdowns in IT equipment (servers) is much greater than energy costs.

However, following global trends, securing sustainable growth through IT has become an important mission for companies Recently, with the expansion of the cloud computing market, the computing environment has become highly integrated and a huge number of servers is in operation. Therefore, the rapidly increasing energy consumption of data centers, which consume up to 40 times more energy than regular buildings, is becoming a social issue.

Therefore, operating a green Internet data center (green IDC) system, which improves the operation method of a conventional Internet data center in an eco- friendly and energy-saving manner, has emerged as an inevitable task.

Regarding the conventional air conditioning system of the green Internet data center, Korea Patent Application Publication No 10-2011-0129514, “Internet data center air conditioning system realizing green computing environment,” has been disclosed, which includes an air conditioner for cooling and ventilation to maintain the indoor temperature of the Internet data center, an air conditioner control device that controls an operation of the air conditioner, a temperature sensor that detects indoor and outdoor (ground and basement) temperatures and provides the information to the air conditioner control device, a cooling duct for cooling the Internet data center from the air conditioner, a ventilation duct for efficiently discharging heat generated from racks equipped with servers and network devices to the outside, and a partition with ventilation associated therewith.

However, the air conditioning system of such a conventional Internet data center had a problem in that energy saving methods were not taken into consideration at all when introducing and ventilating outside air.

In addition, a cooling method of a conventional Internet data center according to another example uses a general mechanical cooling cycle in which power is supplied to a compressor to compress the refrigerant, and the compressed refrigerant discharges heat from a condenser and absorbs heat from the evaporator.

In order to actually cool the exhaust air of about 35° C. generated inside the Internet data center, an individual air-cooled thermo-hygrostat is used, or a cooling tower is installed outside and cooled cold water is supplied to the thermo-hygrostat to cool the room This existing cooling method had a problem in that it did not contribute to energy saving which was based on the premise that a large amount of power was consumed by the compressor accounting for the largest portion of the power consumption of the thermo-hygrostat that must be operated 24 hours a day, 365 days a year.

Recently, as a way to improve the energy efficiency of the Internet data center, an outside air cooling system, which supplies cold outside air directly to the interior of the Internet data center during the winter, has been applied.

### SUMMARY OF INVENTION

### Technical Problem

An object of the present invention is to provide a data center local cooling system with a pre-cooling chiller, in which in response to a temperature of outside air, the pre-cooling chiller may be operated in an optimal operation mode, thereby minimizing the amount of power used to cool a server room, a plurality of in-row air conditioners that cool indoor air are installed between server racks in a computer room, thereby circulating the refrigerant cooled by the in-row air conditioners by using a refrigerant distributor that cools a liquid refrigerant, so that as the liquid refrigerant is used as a refrigerant to cool indoor air, highly efficient heat exchange is possible by using latent heat of evaporation of the refrigerant, and as sensible heat exchange is possible indoors, the refrigerant exists as a gas at room temperature, which prevents condensation from forming inside the server room.

### Technical Solution

A data center local cooling system with a pre-cooling chiller according to the present invention includes a pre-cooling chiller that is installed outside a data center, cools cooling water circulating along an interior thereof by heat exchange with first and second refrigerants, and discharges the cooling water; a plurality of refrigerant distributors that are connected to the pre-cooling chiller through a cooling water flow line through which the cooling water flows and a third refrigerant flow line through which a third refrigerant flows, cool the third refrigerant with heat exchange between the inflow cooling water and the third refrigerant, and discharge the third refrigerant; a plurality of in-row air conditioners that are disposed between server racks in an interior of the data center, are connected to the refrigerant distributors through the third refrigerant flow line through which the third refrigerant flows, cool indoor air with heat exchange between the third refrigerant flowing through the interior and indoor air flowing in a hot zone of the server rack, thereby discharging the cooled indoor air to a cool zone; and a control unit that is electrically connected to the pre-cooling chiller, the plurality of refrigerant distributors, and the plurality of in-row air conditioners, and controls operations of the pre-cooling chiller, the plurality of refrigerant distributors, and the plurality of in-row air conditioners based on an temperature of external air.

In this case, each of the refrigerant distributors according to the present invention includes a third plate-type heat exchanger that is connected to the third refrigerant flow line through the third refrigerant flows and the cooling water flow line through which the cooling water flows, and thereby the third refrigerant in an overheated state flows therein, and is subject to heat exchange with the cooling water to be condensed in a supercooled state and discharged; a receiver that is connected to the third plate-type heat exchanger through the third refrigerant flow line through which the third refrigerant flows, and accommodates the third refrigerant that is condensed and discharged from the third plate-type heat exchanger; and a third refrigerant pump that is connected to the receiver through the third refrigerant flow line through which the third refrigerant flows, and pumps the third refrigerant discharged from the receiver into the plurality of in-row air conditioners.

In addition, each of the in-row air conditioners according to the present invention includes a micro-fin heat exchanger that is subject to heat exchange between the third refrigerant flowing in through the third refrigerant flow line and the indoor air to cool the indoor air; a temperature sensor that is provided on the indoor side of the micro-fin heat exchanger and measures the temperature of air discharged to the indoor; an electronic valve that is provided on the third refrigerant flow line, and selectively adjusts a flow amount of the third refrigerant flowing along the third refrigerant flow line based on the temperature of the third refrigerant measured by the temperature sensor; and a blower that blows the indoor air cooled by heat exchange in the micro-fin heat exchanger into a cool zone.

In addition, the pre-cooling chiller according to the present invention includes a cooling water pump that is provided on the cooling water flow line through which the cooling water flows, and pumps the cooling water flowing along the cooling water flow line; a first cooling cycle that is connected to the cooling water flow line and the first refrigerant flow line through which the first refrigerant circulates, and cools the cooling water with heat exchange between the first refrigerant and the cooling water circulating along the interior; and a second cooling cycle that is connected to the cooling water flow line and the second refrigerant flow line through which the second refrigerant circulates, and cools the cooling water with heat exchange between the second refrigerant and the cooling water circulating along the interior.

Here, the first cooling cycle according to the present invention includes a first plate-type heat exchanger that is connected to the first refrigerant flow line through which the first refrigerant circulates, is connected to the cooling water flow line through which the cooling water flows, and cools the cooling water with heat exchange between the first refrigerant and the cooling water; a first compressor that is connected to the first refrigerant flow line through which the first refrigerant circulates, and selectively compresses and discharges the first refrigerant flowing in along the first refrigerant flow line; a first air-side heat exchanger that is connected to the first refrigerant flow line through which the first refrigerant circulates, cools and condenses the first refrigerant with heat exchange between the first refrigerant flowing in from the first plate-type heat exchanger or the first compressor and external air; a first expansion valve that is connected to the first refrigerant flow line through which the first refrigerant circulates, and selectively expands and discharges the first refrigerant flowing in from the first air-side heat exchanger along the first refrigerant flow line; and a first refrigerant pump that is connected to the first refrigerant flow line through which the first refrigerant circulates, and selectively pumps the first refrigerant flowing in from the first air-side heat exchanger to the first plate-type heat exchanger along the first refrigerant flow line, and the second cooling cycle includes a second plate-type heat exchanger that is connected to the second refrigerant flow line through which the second refrigerant circulates, is connected to the cooling water flow line through which the cooling water flows, and cools the cooling water with heat exchange between the second refrigerant and the cooling water; a second compressor that is connected to the second refrigerant flow line through which the second refrigerant circulates, and selectively compresses and discharges the second refrigerant flowing in along the second refrigerant flow line; a second air-side heat exchanger that is connected to the second refrigerant flow line through which the second refrigerant circulates, cools and condenses the second refrigerant with heat exchange between the second refrigerant flowing in from the second plate-type heat exchanger or the second compressor and external air; a second expansion valve that is connected to the second refrigerant flow line through which the second refrigerant circulates, and selectively expands and discharges the second refrigerant flowing in from the second air-side heat exchanger along the second refrigerant flow line; and a second refrigerant pump that is connected to the second refrigerant flow line through which the second refrigerant circulates, and selectively pumps the second refrigerant flowing in from the second air-side heat exchanger to the second plate-type heat exchanger along the second refrigerant flow line.

In this case, the first plate-type heat exchanger and the second plate-type heat exchanger according to the present invention are connected to the cooling water flow line, and form a circulation route in which the cooling water pumped by the cooling water pump flows into the first plate-type heat exchanger and then flows into the second plate-type heat exchanger, and the cooling water discharged from the second plate-type heat exchanger flows into the refrigerant distributor.

In addition, the first cooling cycle of the pre-cooling chiller according to the present invention is operated in one of a pre-cooling mode that forms a circulation route in which the first refrigerant pumped from the first refrigerant pump flows into the first air-side heat exchanger, the first refrigerant is cooled by heat exchange with external air in the first air-side heat exchanger, the first refrigerant discharged from the first air-side heat exchanger flows into the first plate-type heat exchanger to cool the cooling water by heat exchange with the cooling water in the first plate-type heat exchanger, and the first refrigerant discharges from the first plate-type heat exchanger back to the first refrigerant pump to cool the first refrigerant with external air, and a chiller mode that forms a circulation route of the first refrigerant, in which the first refrigerant, which is compressed at high temperature and high pressure in the first compressor and discharged, flows into the first air-side heat exchanger, the first refrigerant is condensed by heat exchange with the external air in the first air-side heat exchanger, the first refrigerant discharged from the first air-side heat exchanger flows into the first expansion valve, expands in the first expansion valve, and then flows into the first plate-type heat exchanger from the first expansion valve to cool the cooling water by heat exchange with the cooling water in the first plate-type heat exchanger, and the first refrigerant is discharged from the first plate-type heat exchanger back to the first refrigerant pump to cool the refrigerant in the refrigeration cycle.

In addition, the second cooling cycle of the pre-cooling chiller according to the present invention is operated in one of a pre-cooling mode that forms a circulation route in which the second refrigerant pumped from the second refrigerant pump flows into the second air-side heat exchanger, the second refrigerant is cooled by heat exchange with external air in the second air-side heat exchanger, the second refrigerant discharged from the second air-side heat exchanger flows into the second plate-type heat exchanger to cool the cooling water by heat exchange with the cooling water in the second plate-type heat exchanger, and the second refrigerant discharges from the second plate-type heat exchanger back to the second refrigerant pump to cool the second refrigerant with external air, and a chiller mode that forms a circulation route of the second refrigerant, in which the second refrigerant, which is compressed at high temperature and high pressure in the second compressor and discharged, flows into the second air-side heat exchanger, the second refrigerant is condensed by heat exchange with the external air in the second air-side heat exchanger, the second refrigerant discharged from the second air-side heat exchanger flows into the second expansion valve, expands in the second expansion valve, and then flows into the second plate-type heat exchanger from the second expansion valve to cool the cooling water by heat exchange with the cooling water in the second plate-type heat exchanger, and the second refrigerant is discharged from the second plate-type heat exchanger back to the second refrigerant pump to cool the refrigerant in the refrigeration cycle.

In addition, in the pre-cooling refrigerator, both the first cooling cycle and the second cooling cycle are operated in the pre-cooling mode in winter, the first cooling cycle is operated in the pre-cooling mode, and the second cooling cycle is operated in the chiller mode in between-season, and both the first cooling cycle and the second cooling cycle are operated in the chiller mode in summer.

### Advantageous Effects

The effects exhibited by the data center local cooling system with a pre-cooling chiller according to the present invention are as follows.

First, by installing a plurality of in-row air conditioners that cool indoor air at regular intervals between the server racks, there is an advantage that cooled air flows into the server racks without loss, and each of the in-row air conditioners is provided with a flow control valve, the opening/closing and opening degree are adjusted according to the air conditioner discharge temperature deviation to form a uniform temperature distribution, and additional space for the cooling system may be saved, so the cooling system may be considered in existing buildings.

Second, as the liquid refrigerant is cooled and circulated with cooling water through the refrigerant distributor, it is possible to operate the refrigerant at a high temperature due to heat exchange through the latent heat of evaporation of the refrigerant, thereby increasing energy efficiency and preventing condensation inside the server room Since it evaporates at room temperature, it has an advantage of preventing water from forming inside the server room.

Third, the pre-cooling chiller may minimize energy consumption by adjusting operation conditions according to external air conditions.

### BRIEF DESCRIPTION OF THE DRAWINGS

FIG. 1 is an exemplary diagram illustrating a data center local cooling system with a pre-cooling chiller according to an embodiment of the present invention.

FIG. 2 is an exemplary diagram illustrating a pre-cooling chiller according to an embodiment of the present invention.

FIG. 3 is an exemplary diagram illustrating a state where a first cooling cycle and a second cooling cycle of the pre-cooling chiller according to an embodiment of the present invention are operated in a pre-cooling mode.

FIG. 4 is an exemplary diagram illustrating a state where the first cooling cycle is operated in the free-cooling mode and the second cooling cycle of the pre-cooling chiller according to an embodiment of the present invention is operated in a refrigeration cycle mode.

FIG. 5 is an exemplary diagram illustrating a state where the first cooling cycle and the second cooling cycle of the pre-cooling chiller according to an embodiment of the present invention are operated in the refrigeration cycle mode.

FIG. 6 is an exemplary diagram illustrating a refrigerant distributor according to an embodiment of the present invention.

FIG. 7 is an exemplary diagram illustrating a plurality of in-row air conditioners according to an embodiment of the present invention.

FIG. 8 is a flowchart illustrating a control logic of the in-row air conditioner according to an embodiment of the present invention.

FIG. 9 is a flowchart illustrating a control logic of the refrigerant distributor according to an embodiment of the present invention.

FIG. 10 is a flowchart illustrating a control logic of the pre-cooling chiller according to an embodiment of the present invention.

FIG. 11 is a flowchart illustrating a control logic for operation mode 1 (winter mode) of the pre-cooling chiller according to an embodiment of the present invention.

FIG. 12 is a flowchart illustrating a control logic for operation mode 2 (between-season mode) of the pre-cooling chiller according to an embodiment of the present invention.

FIG. 13 is a flowchart illustrating a control logic for operation mode 3 (summer mode) of the pre-cooling chiller according to an embodiment of the present invention.

### BEST MODE FOR INVENTION

The present invention includes a pre-cooling chiller that is installed outside a data center, cools cooling water circulating an interior thereof by heat exchange with first and second refrigerants and discharges the cooling water, a plurality of refrigerant distributors that are connected to the pre-cooling chiller, a cooling water flow line through which the cooling water flows, and a third refrigerant flow line through which a third refrigerant flows, cool the third refrigerant by heat exchange with the inflow cooling water, and discharge the third refrigerant, a plurality of in-row air conditioners that are disposed between server racks inside the data center, are connected to the refrigerant distributors and the third refrigerant flow line through which the third refrigerant flows, cool indoor air by heat exchange between the third refrigerant flowing along the interior and the indoor air flowing in a hot zone of the server racks, and discharge the cooled indoor air to a cool zone of the server racks, and a control unit that is electrically connected to the pre-cooling chiller, the plurality of refrigerant distributors, and the plurality of in-row air conditioners, and controls operations of the pre-cooling chiller, the plurality of refrigerant distributors, and the plurality of in-row air conditioners.

### MODE FOR INVENTION

Hereinafter, preferred embodiments according to the present invention will be described in detail with reference to the attached drawings Prior to this, the terms or words used in this specification and claims should not be construed as limited to their usual or dictionary meanings, and must be interpreted with meaning and concept consistent with the technical idea of the present invention, based on the principle that the inventors may appropriately define the concept of the term in order to explain his or her invention in the best way.

Therefore, the embodiments described in this specification and the configurations illustrated in the drawings are only the most preferred embodiments of the present invention, and do not represent the entire technical idea of the present invention, so it should be understood that at the time of filing this application, there may be equivalent variations that may be replaced.

The present invention relates to a data center local cooling system with a pre-cooling chiller, in which in response to a temperature of outside air, the pre-cooling chiller may be operated in an optimal operation mode, thereby minimizing the amount of power used to cool a server room, a plurality of in-row air conditioners that cool indoor air are installed between server racks in a computer room, thereby circulating the refrigerant cooled by the in-row air conditioners by using a refrigerant distributor that cools a liquid refrigerant, so that as the liquid refrigerant is used as a refrigerant to cool indoor air, highly efficient heat exchange is possible by using latent heat of evaporation of the refrigerant, and as sensible heat exchange is possible indoors, the refrigerant exists as a gas at room temperature, which prevents condensation from forming inside the server room, and the system is as follows with reference to the drawings.

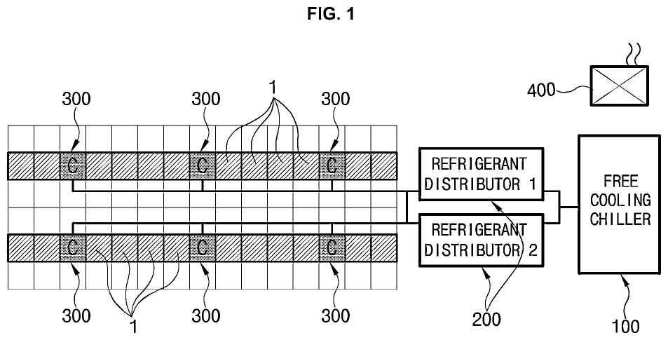

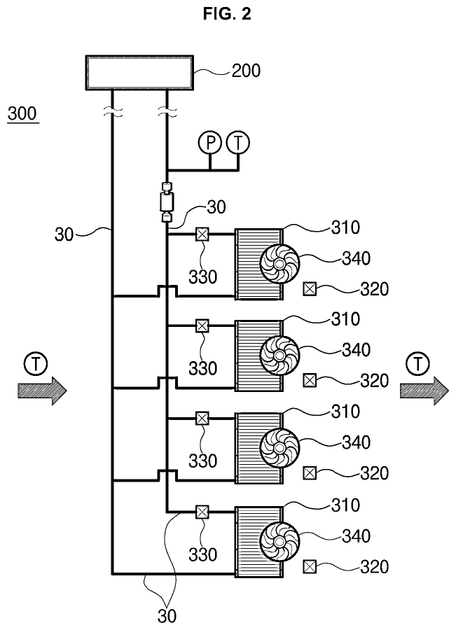

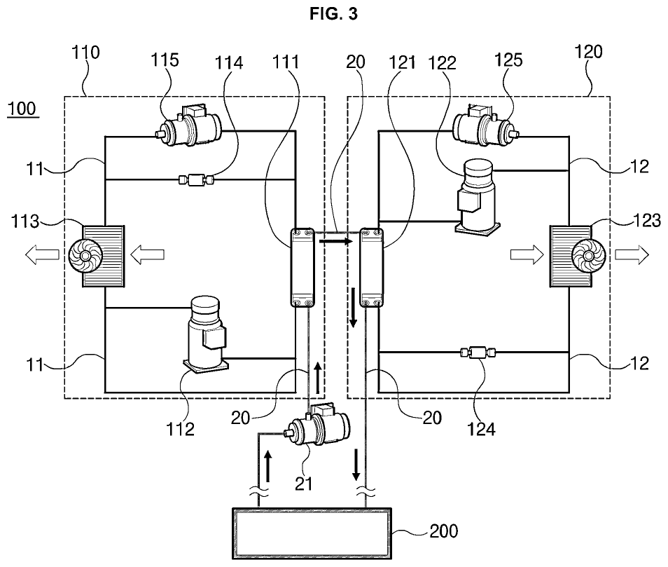

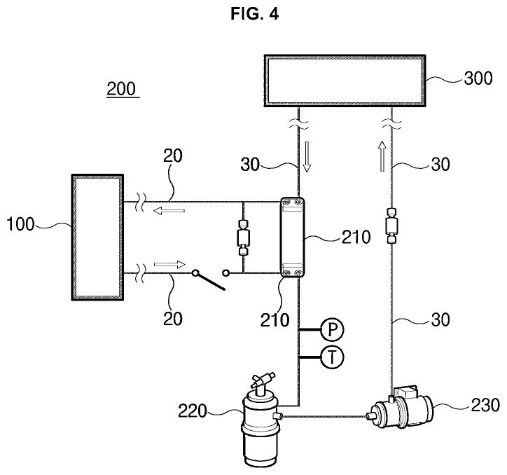

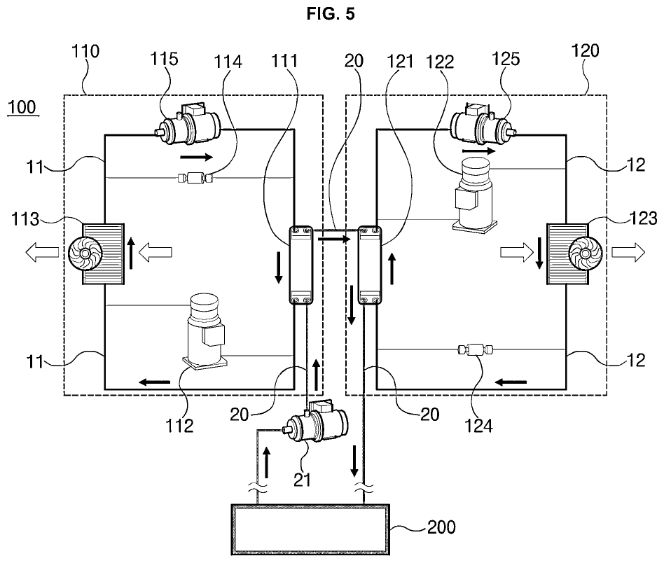

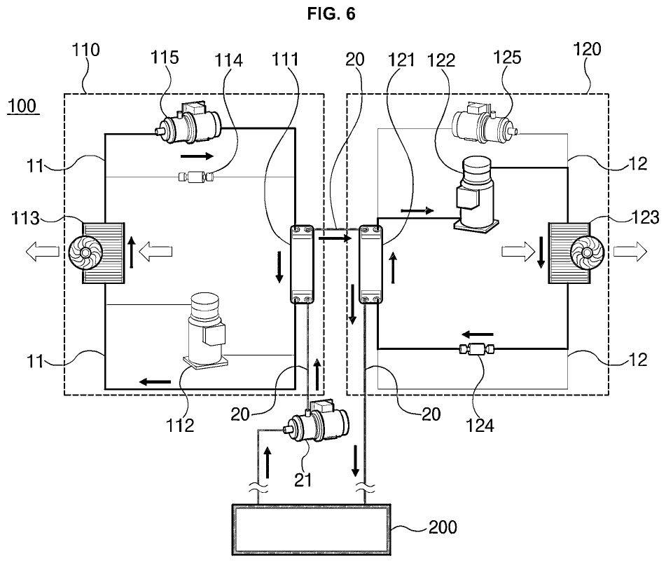

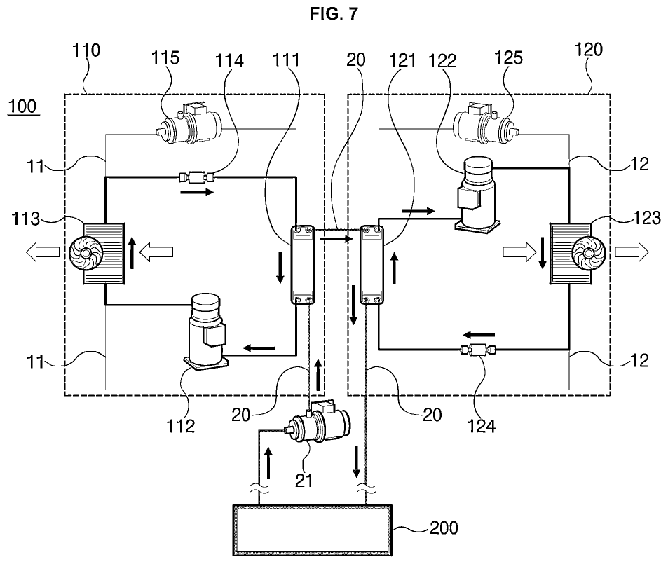

The data center local cooling system according to an embodiment of the present invention referring to FIGS. 1 to 7 includes a pre-cooling chiller 100, a plurality of refrigerant distributors 200, and a plurality of in-row air conditioners 300, and a control unit 400 First, the pre-cooling chiller 100 is installed outside the data center, cools cooling water circulating along the interior by heat exchange with the first and second refrigerants, and discharges the cooling water.

In this case, the pre-cooling chiller 100 includes a first cooling cycle 110 that is provided on a cooling water flow line 20 through which the cooling water flows, is equipped with a cooling water pump 21 to pump the cooling water flowing along the cooling water flow line 20, and includes a first plate-type heat exchanger 111, a first compressor 112, a first air-side heat exchanger 113, a first expansion valve 114, and a first refrigerant pump 115, and a second cooling cycle 120 that includes a second plate-type heat exchanger 121, a second compressor 122, a second air-side heat exchanger 123, a second expansion valve 124, and a second refrigerant pump 125.

Here, the first plate-type heat exchanger 111 and the second plate-type heat exchanger 121 are connected through the cooling water flow line 20 to forms a circulation route, so that the cooling water pumped by the cooling water pump 20 flows to the first plate-type heat exchanger 111 and then flows to the second plate-type heat exchanger 121, and the cooling water discharged from the second plate-type heat exchanger 121 flows to the refrigerant distributor 200.

In addition, the first plate-type heat exchanger 111 is connected to the first compressor 112, the first air-side heat exchanger 113, the first expansion valve 114, and the first refrigerant pump 115 through the first refrigerant flow line 11, in which the first plate-type heat exchanger 111 is connected to the first compressor 112 through the first refrigerant flow line 11 and the first compressor 112 is connected to the first air-side heat exchanger 113 through the first refrigerant flow line 11.

Here, the first air-side heat exchanger 113 is preferably provided with a fan that selectively changes an operation rate, and the operation rate of the fan is changed under the control of the control unit 400.

In this case, the first plate-type heat exchanger 111 is connected to the first air-side heat exchanger 113 through the first refrigerant flow line 11 without passing through the first compressor 112, the first air-side heat exchanger 113 is connected to the first expansion valve 114 and the first refrigerant pump 115 through the first refrigerant flow line 11, and the first expansion valve 114 and the first refrigerant pump 115 are connected to the first plate-type heat exchanger 111 through the first refrigerant flow line 11.

Therefore, the first cooling cycle 110 of the pre-cooling chiller 100 may be operated in a pre-cooling mode in which the first refrigerant circulates from the first refrigerant pump 115 to the first air-side heat exchanger 113, from the first air-side heat exchanger 113 to the first plate-type heat exchanger 111, from the first plate-type heat exchanger 111 back to the first refrigerant pump 115, and in a chiller mode in which the first refrigerant circulates from the first compressor 112 to the first air-side heat exchanger 113, from the first air-side heat exchanger 113 to the first expansion valve 114, from the first expansion valve 114 to the first plate-type heat exchanger 111, from the first plate-type heat exchanger 111 back to the first compressor 112, and may be operated by selecting one of the pre-cooling mode and the chiller mode.

Here, the pre-cooling mode is provided to cool the first refrigerant with external air, and forms a circulation route in which the first refrigerant pumped from the first refrigerant pump 115 flows into the first air-side heat exchanger 113, the first refrigerant is cooled and condensed by heat exchange with external air in the first air-side heat exchanger 113, the first refrigerant discharged from the first air-side heat exchanger 113 flows into the first plate-type heat exchanger 111 to cool the cooling water by heat exchange with the cooling water in the first plate-type heat exchanger 111, and the first refrigerant discharges from the first plate-type heat exchanger 111 back to the first refrigerant pump 115.

The chiller mode is provided to cool the refrigerant by a refrigeration cycle, and forms a circulation route in which the first refrigerant, which is compressed at high temperature and high pressure in the first compressor 112 and discharged, flows into the first air-side heat exchanger 113, the first refrigerant is cooled and condensed by heat exchange with external air in the first air-side heat exchanger 113, the first refrigerant discharged from the first air-side heat exchanger 113 flows into the first expansion valve 114, expands in the first expansion valve 114, and then flows into the first plate-type heat exchanger 111 from the first expansion valve 114 to cool the cooling water by heat exchange with the cooling water in the first plate-type heat exchanger 111, and the first refrigerant is discharged from the first plate-type heat exchanger 111 back to the first refrigerant pump 115.

In addition, the second plate-type heat exchanger 121 is connected to the second compressor 122, the second air-side heat exchanger 123, the second expansion valve 124, and the second refrigerant pump 125 through the second refrigerant flow line 12, in which the second plate-type heat exchanger 121 is connected to the second compressor 122 through the second refrigerant flow line 12, and the second compressor 122 is connected to the second air-side heat exchanger 123 through the second refrigerant flow line 12.

Here, the second air-side heat exchanger 123 is preferably provided with a fan that selectively changes an operation rate, and the operation rate of the fan is changed under the control of the control unit 400.

In this case, the second plate-type heat exchanger 121 is connected to the second air-side heat exchanger 123 through the second refrigerant flow line 12 without passing through the second compressor 122, the second air-side heat exchanger 123 is connected to the second expansion valve 124 and the second refrigerant pump 125 through the second refrigerant flow line 12, and the second expansion valve 124 and the second refrigerant pump 125 are connected to the second plate-type heat exchanger 121 through the second refrigerant flow line 12.

Therefore, the second cooling cycle 120 of the pre-cooling chiller 100 may be operated in a pre-cooling mode in which the second refrigerant circulates from the second refrigerant pump 125 to the second air-side heat exchanger 123, from the second air-side heat exchanger 123 to the second plate-type heat exchanger 121, from the second plate-type heat exchanger 121 back to the second refrigerant pump 125, and in a chiller mode in which the second refrigerant circulates from the second compressor 122 to the second air-side heat exchanger 123, from the second air-side heat exchanger 123 to the second expansion valve 124, from the second expansion valve 124 to the second plate-type heat exchanger 121, from the second plate-type heat exchanger 121 back to the second compressor 122, and may be operated by selecting one of the pre-cooling mode and the chiller mode.

Here, the pre-cooling mode is provided to cool the second refrigerant with external air, and forms a circulation route in which the second refrigerant pumped from the second refrigerant pump 125 flows into the second air-side heat exchanger 123, the second refrigerant is cooled and condensed by heat exchange with external air in the second air-side heat exchanger 123, the second refrigerant discharged from the second air-side heat exchanger 123 flows into the second plate-type heat exchanger 121 to cool the cooling water by heat exchange with the cooling water in the second plate-type heat exchanger 121, and the second refrigerant discharges from the second plate-type heat exchanger 121 back to the second refrigerant pump 125.

The chiller mode is provided to cool the refrigerant by the refrigeration cycle, and forms a circulation route in which the second refrigerant, which is compressed at high temperature and high pressure in the second compressor 122 and discharged, flows into the second air-side heat exchanger 123, the second refrigerant is cooled and condensed by heat exchange with external air in the second air-side heat exchanger 123, the second refrigerant discharged from the second air-side heat exchanger 123 flows into the second expansion valve 124, expands in the second expansion valve 124, and then flows into the second plate-type heat exchanger 121 from the second expansion valve 124 to cool the cooling water by heat exchange with the cooling water in the second plate-type heat exchanger 121, and the second refrigerant is discharged from the second plate-type heat exchanger 121 back to the second refrigerant pump 125.

Therefore, the pre-cooling chiller 100 according to an embodiment of the present invention may be operated in the pre-cooling mode in which the refrigerant is cooled with external air and the chiller mode in which the refrigerant is cooled in the refrigeration cycle, and is operated by selecting one of the pre-cooling mode and the chiller mode in response to the temperature of the external air.

Here, the pre-cooling mode and the chiller mode are selected in response to the temperature (season) of the outside air For example, in winter, since the temperature of the outside air is relatively much lower than the temperature of the indoor air, both the first cooling cycle 110 and the second cooling cycle 120 of the pre-cooling chiller 100 are operated in the pre-cooling mode.

Therefore, in order to cool the first refrigerant with the external air in the winter, the first cooling cycle 110 forms the circulation route of the first refrigerant, in which the first refrigerant pumped from the first refrigerant pump 115 flows into the first air-side heat exchanger 113, the first refrigerant is cooled by heat exchange with the external air in the first air-side heat exchanger 113, the first refrigerant discharged from the first air-side heat exchanger 113 flows into the first plate-type heat exchanger 111 to cool the cooling water by heat exchange with the cooling water in the first plate-type heat exchanger 111, and the first refrigerant discharges from the first plate-type heat exchanger 111 back to the first refrigerant pump 115.

In addition, in order to cool the second refrigerant with the external air, the second cooling cycle 120 also forms the circulation route of the first refrigerant, in which the second refrigerant pumped from the second refrigerant pump 125 flows into the second air-side heat exchanger 123, the second refrigerant is cooled and condensed by heat exchange with the external air in the second air-side heat exchanger 123, the second refrigerant discharged from the second air-side heat exchanger 123 flows into the second plate-type heat exchanger 121 to cool the cooling water by heat exchange with the cooling water in the second plate-type heat exchanger 121, and the second refrigerant discharges from the second plate-type heat exchanger 121 back to the second refrigerant pump 125.

Cooling water cooled by heat exchange with the first and second refrigerants in the first plate-type heat exchanger 111 and the second plate-type heat exchanger 121 is pumped to the refrigerant distributor 200.

In addition, in the between-seasons (spring and fall), since the temperature of the outside air is relatively lower than the temperature of the indoor air, the first cooling cycle 110 is operated in the pre-cooling mode and the second cooling cycle 120 of the pre-cooling chiller 100 is operated in the chiller mode.

Therefore, in order to cool the first refrigerant with the external air in the between-season, the first cooling cycle 110 forms the circulation route of the first refrigerant, in which the first refrigerant pumped from the first refrigerant pump 115 flows into the first air-side heat exchanger 113, the first refrigerant is cooled by heat exchange with the external air in the first air-side heat exchanger 113, the first refrigerant discharged from the first air-side heat exchanger 113 flows into the first plate-type heat exchanger 111 to cool the cooling water by heat exchange with the cooling water in the first plate-type heat exchanger 111, and the first refrigerant discharges from the first plate-type heat exchanger 111 back to the first refrigerant pump 115.

In addition, in order to cool the second refrigerant in the refrigeration cycle, the chiller mode forms the circulation route of the second refrigerant, in which the second refrigerant, which is compressed at high temperature and high pressure in the second compressor 122 and discharged, flows into the second air-side heat exchanger 123, the second refrigerant is cooled and condensed by heat exchange with the external air in the second air-side heat exchanger 123, the second refrigerant discharged from the second air-side heat exchanger 123 flows into the second expansion valve 124, expands in the second expansion valve 124, and then flows into the second plate-type heat exchanger 121 from the second expansion valve 124 to cool the cooling water by heat exchange with the cooling water in the second plate-type heat exchanger 121, and the second refrigerant is discharged from the second plate-type heat exchanger 121 back to the second refrigerant pump 125.

Cooling water cooled by heat exchange with the first and second refrigerants in the first plate-type heat exchanger 111 and the second plate-type heat exchanger 121 is pumped to the refrigerant distributor 200.

In addition, in summer, since the temperature of the outside air is relatively higher than the temperature of the indoor air, both the first cooling cycle 110 and the second cooling cycle 120 of the pre-cooling chiller 100 are operated in the chiller mode.

Therefore, in order to cool the first refrigerant in the refrigeration cycle in summer, the chiller mode forms the circulation route of the first refrigerant, in which the first refrigerant, which is compressed at high temperature and high pressure in the first compressor 112 and discharged, flows into the first air-side heat exchanger 113, the first refrigerant is cooled and condensed by heat exchange with the external air in the first air-side heat exchanger 113, the first refrigerant discharged from the first air-side heat exchanger 113 flows into the first expansion valve 114, expands in the first expansion valve 114, and then flows into the first plate-type heat exchanger 111 from the first expansion valve 114 to cool the cooling water by heat exchange with the cooling water in the first plate-type heat exchanger 111, and the first refrigerant is discharged from the first plate-type heat exchanger 111 back to the first refrigerant pump 115.

In addition, in order to cool the second refrigerant in the refrigeration cycle, the chiller mode forms the circulation route of the second refrigerant, in which the second refrigerant, which is compressed at high temperature and high pressure in the second compressor 122 and discharged, flows into the second air-side heat exchanger 123, the second refrigerant is cooled and condensed by heat exchange with the external air in the second air-side heat exchanger 123, the second refrigerant discharged from the second air-side heat exchanger 123 flows into the second expansion valve 124, expands in the second expansion valve 124, and then flows into the second plate-type heat exchanger 121 from the second expansion valve 124 to cool the cooling water by heat exchange with the cooling water in the second plate-type heat exchanger 121, and the second refrigerant is discharged from the second plate-type heat exchanger 121 back to the second refrigerant pump 125.

Cooling water cooled by heat exchange with the first and second refrigerants in the first plate-type heat exchanger 111 and the second plate-type heat exchanger 121 is pumped to the refrigerant distributor 200.

Therefore, the pre-cooling chiller 100 is a pre-cooling system including the refrigerant pump that pumps liquid refrigerant, and the operation mode is selected and operated as one of the pre-cooling mode and the chiller mode depending on the external air temperature conditions, so that energy consumption for cooling the colling water may be minimized.

The refrigerant distributor 200 according to an embodiment of the present invention is connected to the pre-cooling chiller 100 through the cooling water flow line 20 through which the cooling water flows and the third refrigerant flow line 30 through which the third refrigerant flows, cools the third refrigerant with heat exchange between the inflow cooling water and the third refrigerant, and discharges the third refrigerant.

In this case, the refrigerant distributor 200 may be provided as one or more than one, and includes a third plate-type heat exchanger 210, a receiver 220, and a third refrigerant pump 230.

The third plate-type heat exchanger 210 is connected to the third refrigerant flow line 30 through the third refrigerant flows and the cooling water flow line 20 through which the cooling water flows, and thereby the third refrigerant in an overheated state flows therein, and is subject to heat exchange with the cooling water to be condensed in a supercooled state and discharged.

In this case, the third plate-type heat exchanger 210 is connected to a plurality of in-row air conditioners 300 through the third refrigerant flow line 30 to introduce the overheated third refrigerant from the in-row air conditioners 300, connected to the pre-cooling chiller 100 through the cooling water flow line 20 to introduce the cooling water cooled from the pre-cooling chiller 100, is subject to heat exchange between the in-flow cooling water and the third refrigerant, and causes the third refrigerant to be condensed in a supercooled state and discharged.

In addition, the cooling water flow line 20 connected to the third plate-type heat exchanger 210 is provided with a bypass line, and an open/close valve is provided on the bypass line, so that the cooling water flowing in the pre-cooling chiller 100 may be bypassed directly to the pre-cooling chiller 100 along the cooling water flow line 20 by opening the bypass line, without passing through the third plate-type heat exchanger 210.

In addition, the receiver 220 is connected to the third plate-type heat exchanger 210 through the third refrigerant flow line 30 through which the third refrigerant flows, and accommodates the third refrigerant that is condensed and discharged from the third plate-type heat exchanger 210.

Here, the receiver 220 discharges the refrigerant flowing along the third refrigerant flow line 30 in only a liquid state, allowing only the liquid refrigerant to flow into the third refrigerant pump 230. A temperature sensor and a pressure sensor are provided on the third refrigerant flow line 30, which connects the third plate-type heat exchanger 210 and the receiver 220 in the third refrigerant flow line 30, and thereby the temperature and pressure of the refrigerant flowing from the third plate-type heat exchanger 210 to the receiver 220 through the third refrigerant flow line 30 may be measured.

In addition, the third refrigerant pump 230 is connected to the receiver 220 through the third refrigerant flow line 30 through which the third refrigerant flows, and pumps the third refrigerant discharged from the receiver 220 into the plurality of in-row air conditioners 300.

In this case, the third refrigerant pump 230 is operated through subcooling degree control, and a saturation temperature of the circulating refrigerant is determined depending on the capacity of the server rack 1 and the temperature of the supplied cooling water. The larger the capacity of the server rack, the more preferably it is operated to obtain a lower water temperature.

In addition, the in-row air conditioner 300 according to an embodiment of the present invention is disposed between the server racks 1 in the interior of the data center, is connected to the refrigerant distributor 200 through the third refrigerant flow line 30 through which the third refrigerant flows, cools the indoor air with heat exchange between the third refrigerant flowing through the interior and the indoor air flowing in the hot zone of the server rack 1, thereby discharging the cooled indoor air to the cool zone.

In this case, the plurality of in-row air conditioners 300 are preferably disposed at regular intervals between the server racks 1 in the interior of the data center, and include micro-fin heat exchangers 310, temperature sensors 320, electronic valves 330, and blowers 340.

The micro-fin heat exchanger 310 is capable of a high heat exchange amount compared to the volume, is connected to the refrigerant distributor 200 through the third refrigerant flow line 30, and is subject to heat exchange between the liquid third refrigerant flowing in through the third refrigerant flow line 30 and the indoor air to cool the indoor air.

In this case, the micro-fin heat exchanger 310 is preferably equipped with a fan that selectively changes the operation rate, and the operation rate of the fan is changed under the control of the control unit 400.

The temperature sensor 320 is provided on the indoor side of the micro-fin heat exchanger 310 and measures the temperature of air discharged to the indoor.

In this case, the measured temperature is applied to the control unit 400, and the control unit 400 controls the opening/closing and opening degree of the electronic valve 330.

The electronic valve 330 is provided on the third refrigerant flow line 30, and selectively adjusts the flow amount of the third refrigerant flowing along the third refrigerant flow line 30 based on the temperature of the third refrigerant measured by the temperature sensor.

A preferred embodiment of the electronic valve 330 is provided on the discharge side of the micro-fin heat exchanger 310 in the third refrigerant flow line 30, and selectively adjusts the flow amount of the third refrigerant flowing along the third refrigerant flow line 30 based on the temperature measured by the temperature sensor 320.

Here, each of the plurality of in-row air conditioners 300 is preferably provided with the temperature sensor 320 and the electronic valve 330, and the air discharged from each micro-fin heat exchanger 310 is adjusted by control of the control unit 400 to be discharged at a uniform temperature.

In addition, the blower 340 blows the indoor air cooled by heat exchange in the micro-fin heat exchanger 310 into the cool zone.

In this case, as the blower 340, it is preferable to use an EC motor which is excellent in terms of power use, and the operation of the blower 340 may be adjusted according to the indoor load by applying a built-in inverter.

The control unit 400 according to an embodiment of the present invention is electrically connected to the pre-cooling chiller 100, the plurality of refrigerant distributors 200, and the plurality of in-row air conditioners 300, and controls the operations of the pre-cooling chiller 100, the plurality of refrigerant distributors 200, and the plurality of in-row air conditioners 300 based on the temperature of the external air.

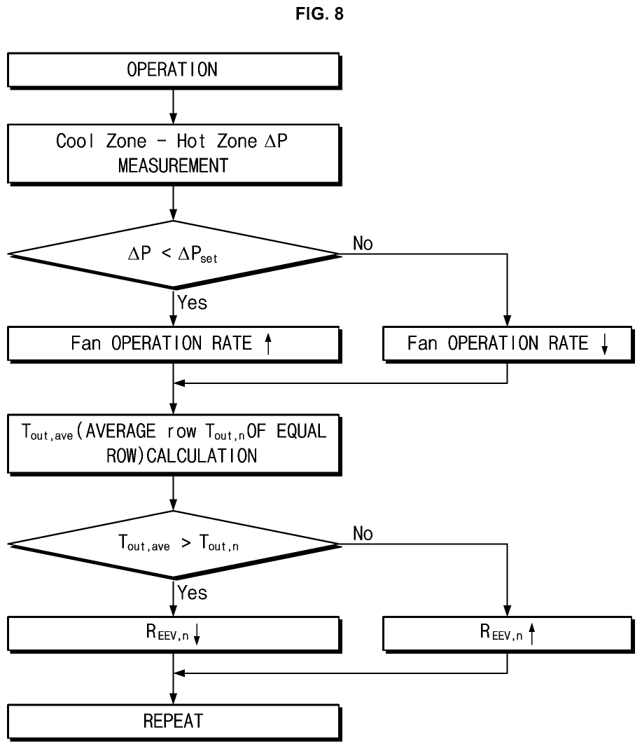

With reference to FIGS. 8 to 13, the control of the control unit 400 based on external air is as follows.

First, looking at the control of the in-row air conditioner 300 with reference to FIG. 8, the blower 340 and the electronic valve 330 of the in-row air conditioner 300 are controlled by the control unit 400, and the pressure loss between the cool zone and the hot zone of the server room on the containment side is measured.

At this time, air pressures of the cool zone and the hot zone of the server room are measured using air pressure sensors (not illustrated) provided in each of the cool zone and hot zone of the server room, respectively, and the pressure loss between the cool zone and the hot zone in which the air pressures are measured is calculated.

Next, the calculated pressure loss is compared with a set value (pressure loss) to derive a comparison value.

Next, an increase or decrease in the fan operation rate of the blower 340 is controlled based on the derived comparison value At this time, if the set value is higher than the measured pressure loss, the fan operation rate of the blower 340 is increased, and if the set value is lower than the measured pressure loss, the fan operation rate of the blower 340 is decreased.

In addition, the blower 340 may be controlled independently among the plurality of in-row air conditioners 300 installed in the same row.

In addition, the electronic valve 330 is controlled based on the temperature of the air discharged through the micro-fin heat exchanger 310. First, the temperature of the air discharged from the plurality of in-row air conditioners 300 installed in the same row is measured.

At this time, the temperature of the air discharged from each of the plurality of in-row air conditioners 300 installed in the same row is measured, and an average value of each measured discharged air temperature is calculated.

Next, the temperature of the discharged air is compared with the average value. At this time, it is preferable to compare the average value with the temperature of the discharged air of each in-row air conditioner 300.

Next, the opening/closing and opening degree of the electronic valve 330 are controlled based on the comparison value At this time, if the discharged air temperature of the in-row air conditioner 300 is higher than the average value, the opening degree of the electronic valve 330 is narrowed to decrease the flow amount of the third refrigerant, and if the discharged air temperature of the in-row air conditioner 300 is lower than the average value, the opening degree of the electronic valve 330 is widened to increase the flow amount of the third refrigerant.

Therefore, the temperature inside the computer room may be uniformly controlled by independently controlling the electronic valves 330 of each of the plurality of in-row air conditioners 300 installed in the same row.

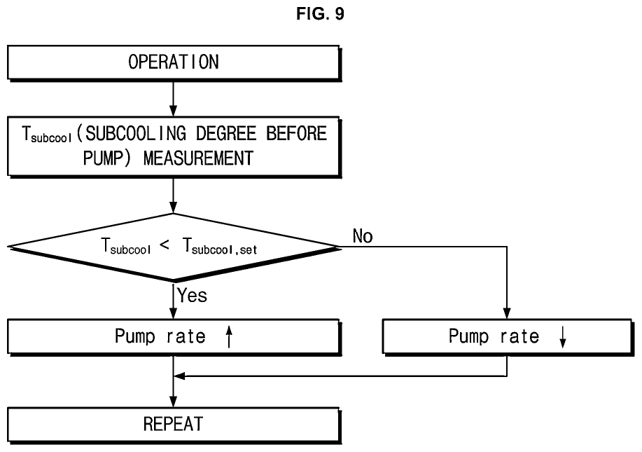

Looking at the control of the refrigerant distributor 200 with reference to FIG. 9, the third refrigerant pump 230 of the refrigerant distributor 200 is controlled by the control unit 400 First, the subcooling degree of the third refrigerant of the third refrigerant pump 230 on the inlet side is measured.

Next is the measured subcooling degree is compared with a set value (subcooling degree) At this time, the subcooling degree of the third refrigerant measured on the inlet side of the third refrigerant pump 230 is compare with the set value (subcooling degree) to derive a comparison value.

Next, an increase or decrease in the speed of the third refrigerant pump 230 is controlled based on the derived comparison value. At this time, if the measured subcooling degree of the third refrigerant is higher than the set value, the speed of the third refrigerant pump 230 is decreased, and if the measured subcooling degree of the third refrigerant is lower than the set value, the speed of the third refrigerant pump 230 is increased.

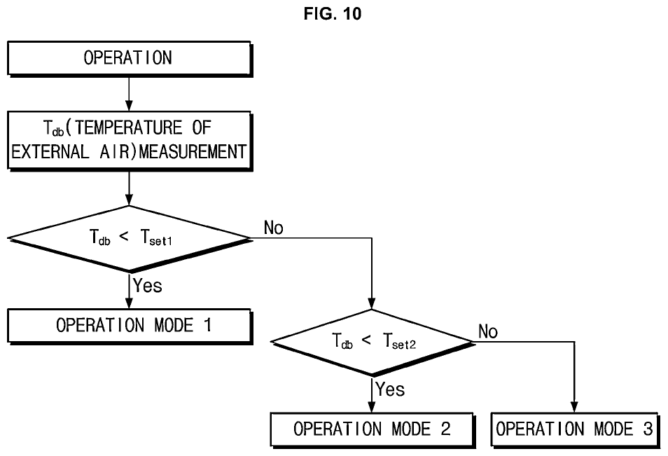

Looking at the control of the pre-cooling chiller 100 with reference to FIGS. 10 to 13, the pre-cooling chiller 100 is controlled in winter, between-season, and summer modes by the control unit 400, and is initially controlled by selecting the operation mode according to the temperature of the outside air, and the operation mode is changed based on the indoor load during operation.

Referring to FIG. 10, first, the temperature of the outside air is measured. The temperature of the outside air is measured through a temperature sensor provided outside the data center. Next, the measured temperature of the outside air is compared with set value 1 (temperature of the outside air) to derive a comparison value.

Next, operation mode 1 (winter mode) is selected based on the derived comparison value At this time, if the temperature of the outside air is lower than the set value 1, the operation is controlled to operate in the operation mode 1 (winter mode), and if the temperature of the outside air is higher than the set value 1, the temperature of the outside air is compared with set value 2.

Next, the measured temperature of the outside air is compared with the set value 2 (temperature of the outside air) to derive the comparison value. Next, based on the derived comparison value, the operation mode 2 (between-season mode) or the operation mode 3 (summer mode) is derived is selected, and at this time, if the temperature of the outside air is lower than the set value 2, the operation mode 2 (between-season mode) is selected to be controlled, and if the temperature of the outside air is higher than the set value 2, operation mode 2 (between-season mode) is selected to be controlled.

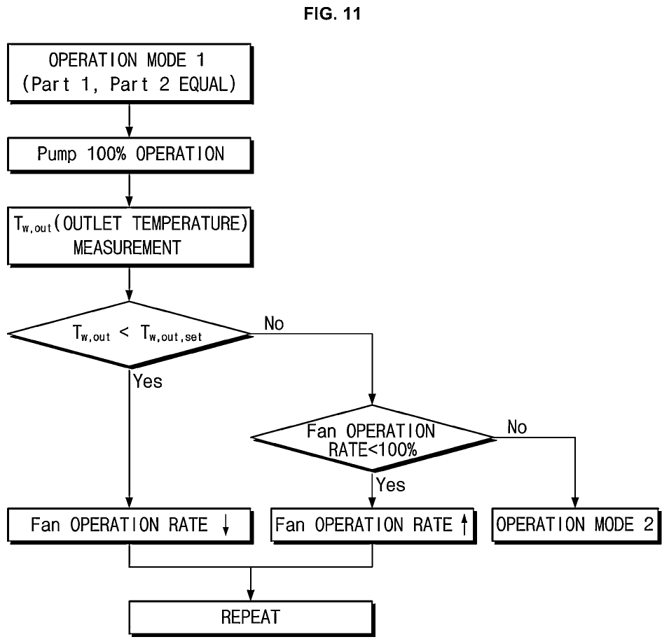

Here, in operation mode 1 (winter mode) with reference to FIG. 11, both the first cooling cycle 110 and the second cooling cycle 120 of the pre-cooling chiller 100 are controlled in the pre-cooling mode First, the first refrigerant pump 115 and the second refrigerant pump 125 are controlled to operate at 100% (maximum rotation speed), and the outlet temperature of the cooling water discharged to the refrigerant distributor 200 along the cooling water flow line (20) is measured. Next, the measured outlet temperature of the cooling water is compared with the set value (cooling water outlet temperature) to derive a comparison value.

Next, the operation rate of the fan provided in each of the first air-side heat exchanger 113 and the second air-side heat exchanger 123 is controlled based on the derived comparison value, and if the measured outlet temperature of the cooling water is lower than the set value, the fan operation rate is decreased, and if the measured outlet temperature of the cooling water is higher than the set value, the current fan operation rate is compared with the 100% fan operation rate to derive the comparison value.

At this time, if the current fan operation rate is lower than 100% fan operation rate, the fan operation rate is increased, and if the current fan operation rate is higher than 100% fan operation rate, the operation mode 2 (between-season mode) is switched.

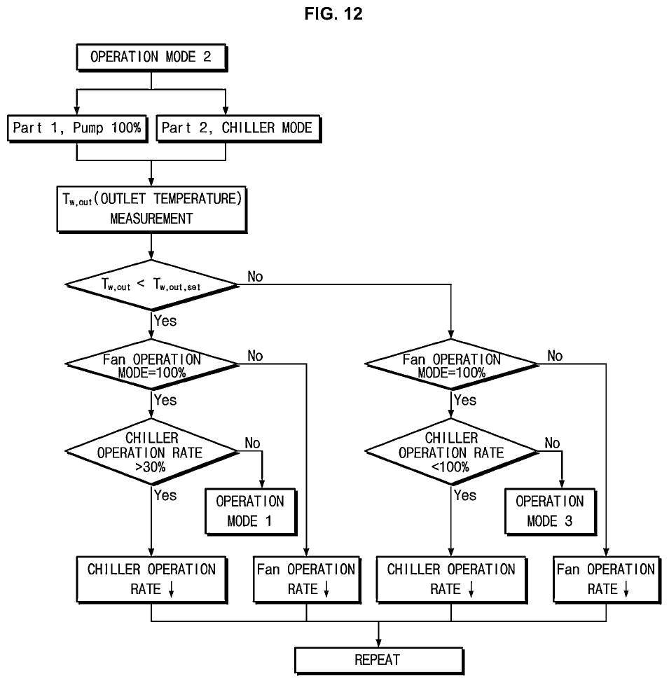

In the operation mode 2 (between-season mode) with reference to FIG. 12, the first cooling cycle 110 of the pre-cooling chiller 100 is controlled in the pre-cooling mode, and the second cooling cycle 120 is controlled in the chiller mode. First, the first refrigerant pump 115 is controlled to operate at 100% (maximum rotation speed), and the second cooling cycle 120 is switched to the chiller mode, so that the second refrigerant circulates through the second compressor 122, the second air-side heat exchanger 123, the second expansion valve 124, and the second plate-type heat exchanger 121 along the second refrigerant flow line 20.

Next, the outlet temperature of the cooling water discharged to the refrigerant distributor 200 along the cooling water flow line 20 is measured, and then the measured outlet temperature of the cooling water is compared with the set value (cooling water outlet temperature) to derive a comparison value.

Next, based on the derived comparison values, it is compared whether the operation rate and 100% operation rate of the fan provided in each of the first air-side heat exchanger 113 and the second air-side heat exchanger 123 are equal. At this time, if the measured outlet temperature of the cooling water is lower than the set value and the fan operation rate is equal to the 100% operation rate, the operation rate of the second cooling cycle 120 is compared with the 30% operation rate.

Here, if the operation rate of the second cooling cycle 120 is higher than 30% operation rate, the operation rate of the second cooling cycle 120 is decreased, and if the operation rate of the second cooling cycle 120 is lower than 30% operation rate, the operation rate is lowered. Controlled by switching to the operation mode 1 (winter season) is controlled to be switched.

In addition, it is compared whether the operation rate and 100% operation rate of the fan provided in each of the first air-side heat exchanger 113 and the second air-side heat exchanger 123 are equal, and if not, the operation rate of the fan is decreased.

In addition, if the measured outlet temperature of the cooling water is higher than the set value and the fan operation rate is equal to the 100% operation rate, the operation rate of the second cooling cycle 120 is compared with the 100% operation rate.

Here, if the operation rate of the second cooling cycle 120 is lower than the 100% operation rate, the operation rate of the second cooling cycle 120 is increased, and if the operation rate of the second cooling cycle 120 is equal to or higher than the 100% operation rate, the operation mode 3 (summer mode) is controlled to be switched.

In addition, it is compared whether the operation rate and 100% operation rate of the fan provided in each of the first air-side heat exchanger 113 and the second air-side heat exchanger 123 are equal, and if not, the operation rate of the fan is decreased.

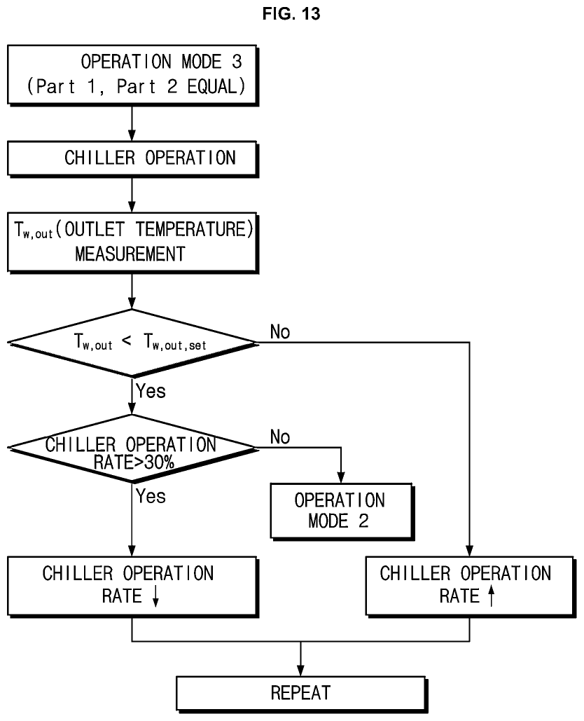

In the operation mode 3 (summer mode) with reference to FIG. 13, both the first cooling cycle 110 and the second cooling cycle 120 of the pre-cooling chiller 100 are controlled in the chiller mode First, the first cooling cycle 110 and the second cooling cycle 120 are switched to the chiller mode, and the first refrigerant circulates through the first compressor 112, the first air-side heat exchanger 113, and the first expansion valve 114, and the first plate-type heat exchanger 111 along the first refrigerant flow line 10 The second refrigerant circulates through the second compressor 122, the second air-side heat exchanger 123, the second expansion valve 124, and the second plate-type heat exchanger 121 along the second refrigerant flow line 20.

Next, the outlet temperature of the cooling water discharged to the refrigerant distributor 200 along the cooling water flow line 20 is measured, and then the measured outlet temperature of the cooling water is compared with the set value (cooling water outlet temperature) to derive the comparison value If the measured outlet temperature of the cooling water based on the derived comparison value is lower than the set value (cooling water outlet temperature), the operation rates of the first cooling cycle 110 and the second cooling cycle 120 are compared with the 30% operation rate, and, if the operation rates of the first cooling cycle 110 and the second cooling cycle 120 are higher than the 30% operation rate, the operation rates of the first cooling cycle 110 and the second cooling cycle 120 are decreased. If the operation rates of the first cooling cycle 110 and the second cooling cycle 120 are lower than 30% operation rate, the operation mode 2 (between-season mode) is controlled to be switched.

In addition, if the outlet temperature of the cooling water measured based on the derived comparison value is higher than the set value (cooling water outlet temperature), the operation rates of the first cooling cycle 110 and the second cooling cycle 120 are controlled to increase.

The present invention has been described with reference to the embodiments illustrated in the drawings, but these are merely exemplary, and those skilled in the art will understand that various modifications and equivalent other embodiments are possible therefrom Therefore, the true scope of technical protection of the present invention should be determined by the technical spirit of the attached claims.

1. A data center local cooling system with a pre-cooling chiller comprising:
a pre-cooling chiller that is installed outside a data center, cools cooling water circulating along an interior thereof by heat exchange with first and second refrigerants, and discharges the cooling water;
a plurality of refrigerant distributors that are connected to the pre-cooling chiller through a cooling water flow line through which the cooling water flows and a third refrigerant flow line through which a third refrigerant flows, cool the third refrigerant with heat exchange between the inflow cooling water and the third refrigerant, and discharge the third refrigerant;
a plurality of in-row air conditioners that are disposed between server racks in an interior of the data center, are connected to the refrigerant distributors through the third refrigerant flow line through which the third refrigerant flows, cool indoor air with heat exchange between the third refrigerant flowing through the interior and indoor air flowing in a hot zone of the server rack, thereby discharging the cooled indoor air to a cool zone; and
a control unit that is electrically connected to the pre-cooling chiller, the plurality of refrigerant distributors, and the plurality of in-row air conditioners, and controls operations of the pre-cooling chiller, the plurality of refrigerant distributors, and the plurality of in-row air conditioners based on a temperature of external air.

2. The data center local cooling system with a pre-cooling chiller of claim 1, wherein each of the refrigerant distributors includes
a third plate-type heat exchanger that is connected to the third refrigerant flow line through the third refrigerant flows and the cooling water flow line through which the cooling water flows, and thereby the third refrigerant in an overheated state flows therein, and is subject to heat exchange with the cooling water to be condensed in a supercooled state and discharged;
a receiver that is connected to the third plate-type heat exchanger through the third refrigerant flow line through which the third refrigerant flows, and accommodates the third refrigerant that is condensed and discharged from the third plate-type heat exchanger; and
a third refrigerant pump that is connected to the receiver through the third refrigerant flow line through which the third refrigerant flows, and pumps the third refrigerant discharged from the receiver into the plurality of in-row air conditioners.

3. The data center local cooling system with a pre-cooling chiller of claim 1, wherein each of the in-row air conditioners includes
a micro-fin heat exchanger that is subject to heat exchange between the third refrigerant flowing in through the third refrigerant flow line and the indoor air to cool the indoor air;
a temperature sensor that is provided on the indoor side of the micro-fin heat exchanger and measures the temperature of air discharged to the indoor;
an electronic valve that is provided on the third refrigerant flow line, and selectively adjusts a flow amount of the third refrigerant flowing along the third refrigerant flow line based on the temperature of the third refrigerant measured by the temperature sensor; and
a blower that blows the indoor air cooled by heat exchange in the micro-fin heat exchanger into a cool zone.

4. The data center local cooling system with a pre-cooling chiller of claim 1, wherein the pre-cooling chiller includes
a cooling water pump that is provided on the cooling water flow line through which the cooling water flows, and pumps the cooling water flowing along the cooling water flow line;
a first cooling cycle that is connected to the cooling water flow line and the first refrigerant flow line through which the first refrigerant circulates, and cools the cooling water with heat exchange between the first refrigerant and the cooling water circulating along the interior; and
a second cooling cycle that is connected to the cooling water flow line and the second refrigerant flow line through which the second refrigerant circulates, and cools the cooling water with heat exchange between the second refrigerant and the cooling water circulating along the interior.

5. The data center local cooling system with a pre-cooling chiller of claim 4, wherein the first cooling cycle includes
a first plate-type heat exchanger that is connected to the first refrigerant flow line through which the first refrigerant circulates, is connected to the cooling water flow line through which the cooling water flows, and cools the cooling water with heat exchange between the first refrigerant and the cooling water;
a first compressor that is connected to the first refrigerant flow line through which the first refrigerant circulates, and selectively compresses and discharges the first refrigerant flowing in along the first refrigerant flow line;
a first air-side heat exchanger that is connected to the first refrigerant flow line through which the first refrigerant circulates, cools and condenses the first refrigerant with heat exchange between the first refrigerant flowing in from the first plate-type heat exchanger or the first compressor and external air;
a first expansion valve that is connected to the first refrigerant flow line through which the first refrigerant circulates, and selectively expands and discharges the first refrigerant flowing in from the first air-side heat exchanger along the first refrigerant flow line; and
a first refrigerant pump that is connected to the first refrigerant flow line through which the first refrigerant circulates, and selectively pumps the first refrigerant flowing in from the first air-side heat exchanger to the first plate-type heat exchanger along the first refrigerant flow line, and
the second cooling cycle includes
a second plate-type heat exchanger that is connected to the second refrigerant flow line through which the second refrigerant circulates, is connected to the cooling water flow line through which the cooling water flows, and cools the cooling water with heat exchange between the second refrigerant and the cooling water;
a second compressor that is connected to the second refrigerant flow line through which the second refrigerant circulates, and selectively compresses and discharges the second refrigerant flowing in along the second refrigerant flow line;
a second air-side heat exchanger that is connected to the second refrigerant flow line through which the second refrigerant circulates, cools and condenses the second refrigerant with heat exchange between the second refrigerant flowing in from the second plate-type heat exchanger or the second compressor and external air;
a second expansion valve that is connected to the second refrigerant flow line through which the second refrigerant circulates, and selectively expands and discharges the second refrigerant flowing in from the second air-side heat exchanger along the second refrigerant flow line; and
a second refrigerant pump that is connected to the second refrigerant flow line through which the second refrigerant circulates, and selectively pumps the second refrigerant flowing in from the second air-side heat exchanger to the second plate-type heat exchanger along the second refrigerant flow line.

6. The data center local cooling system with a pre-cooling chiller of claim 5, wherein the first plate-type heat exchanger and the second plate-type heat exchanger are connected to the cooling water flow line, and form a circulation route in which the cooling water pumped by the cooling water pump flows into the first plate-type heat exchanger and then flows into the second plate-type heat exchanger, and the cooling water discharged from the second plate-type heat exchanger flows into the refrigerant distributor.

7. The data center local cooling system with a pre-cooling chiller of claim 5, wherein the first cooling cycle of the pre-cooling chiller is operated in one of
a pre-cooling mode that forms a circulation route in which the first refrigerant pumped from the first refrigerant pump flows into the first air-side heat exchanger, the first refrigerant is cooled by heat exchange with external air in the first air-side heat exchanger, the first refrigerant discharged from the first air-side heat exchanger flows into the first plate-type heat exchanger to cool the cooling water by heat exchange with the cooling water in the first plate-type heat exchanger, and the first refrigerant discharges from the first plate-type heat exchanger back to the first refrigerant pump to cool the first refrigerant with external air, and
a chiller mode that forms a circulation route of the first refrigerant, in which the first refrigerant, which is compressed at high temperature and high pressure in the first compressor and discharged, flows into the first air-side heat exchanger, the first refrigerant is condensed by heat exchange with the external air in the first air-side heat exchanger, the first refrigerant discharged from the first air-side heat exchanger flows into the first expansion valve, expands in the first expansion valve, and then flows into the first plate-type heat exchanger from the first expansion valve to cool the cooling water by heat exchange with the cooling water in the first plate-type heat exchanger, and the first refrigerant is discharged from the first plate-type heat exchanger back to the first refrigerant pump to cool the refrigerant in the refrigeration cycle.

8. The data center local cooling system with a pre-cooling chiller of claim 7, wherein the second cooling cycle of the pre-cooling chiller is operated in one of
a pre-cooling mode that forms a circulation route in which the second refrigerant pumped from the second refrigerant pump flows into the second air-side heat exchanger, the second refrigerant is cooled by heat exchange with external air in the second air-side heat exchanger, the second refrigerant discharged from the second air-side heat exchanger flows into the second plate-type heat exchanger to cool the cooling water by heat exchange with the cooling water in the second plate-type heat exchanger, and the second refrigerant discharges from the second plate-type heat exchanger back to the second refrigerant pump to cool the second refrigerant with external air, and
a chiller mode that forms a circulation route of the second refrigerant, in which the second refrigerant, which is compressed at high temperature and high pressure in the second compressor and discharged, flows into the second air-side heat exchanger, the second refrigerant is condensed by heat exchange with the external air in the second air-side heat exchanger, the second refrigerant discharged from the second air-side heat exchanger flows into the second expansion valve, expands in the second expansion valve, and then flows into the second plate-type heat exchanger from the second expansion valve to cool the cooling water by heat exchange with the cooling water in the second plate-type heat exchanger, and the second refrigerant is discharged from the second plate-type heat exchanger back to the second refrigerant pump to cool the refrigerant in the refrigeration cycle.

9. The data center local cooling system with a pre-cooling chiller of claim 8, wherein in the pre-cooling refrigerator,
both the first cooling cycle and the second cooling cycle are operated in the pre-cooling mode in winter,
the first cooling cycle is operated in the pre-cooling mode, and the second cooling cycle is operated in the chiller mode in between-season, and
both the first cooling cycle and the second cooling cycle are operated in the chiller mode in summer.
